(19) United States
(12) Patent Application Publication
(10) Pub. No.: US 2016/0071949 A1
(43) Pub. Date: Mar. 10, 2016

(54) METHOD FOR MANUFACTURING SILICON CARBIDE SEMICONDUCTOR DEVICE

(71) Applicant: SUMITOMO ELECTRIC INDUSTRIES, LTD., Osaka-shi (JP)

(72) Inventor: Toru Hiyoshi, Osaka-shi (JP)

(21) Appl. No.: 14/790,780

(22) Filed: Jul. 2, 2015

(30) Foreign Application Priority Data
Sep. 9, 2014 (JP) 2014-183326

(51) Int. Cl. H01L 29/66; H01L 21/02; H01L 29/06; H01L 21/265; H01L 29/16; H01L 21/04

(52) U.S. Cl. CPC H01L 29/66068; H01L 29/1608; H01L 21/048; H01L 29/0696; H01L 21/265; H01L 21/02529; H01L 29/66712

(57) ABSTRACT

A method for manufacturing a silicon carbide semiconductor device includes the following steps. When viewed in a direction perpendicular to a main surface, a silicon carbide substrate has a connection region provided to include an end portion of one side, an apex of a first body region nearest to the end portion, and an apex of a second body region nearest to the end portion, the connection region being electrically connected to both the first body region and the second body region, the connection region having the second conductivity type. When viewed in a direction parallel to the main surface, the first drift region and the second drift region are provided between a gate insulating film and the connection region. The connection region, the first body region, and the second body region are formed by ion implantation.

### BACKGROUND OF THE INVENTION

1. Field of the Invention

The present invention relates to a method for manufacturing a silicon carbide semiconductor device, particularly, relates to a method for manufacturing a silicon carbide semiconductor device including a step of forming a gate insulating film.

2. Description of the Background Art

In recent years, in order to achieve high breakdown voltage, low loss, and utilization of semiconductor devices under a high temperature environment, silicon carbide has begun to be adopted as a material for a semiconductor device. Silicon carbide is a wide band gap semiconductor having a band gap larger than that of silicon, which has been conventionally widely used as a material for semiconductor devices. Hence, by adopting silicon carbide as a material for a semiconductor device, the semiconductor device can have a high breakdown voltage, reduced on resistance, and the like. Further, the semiconductor device thus adopting silicon carbide as its material has characteristics less deteriorated even under a high temperature environment than those of a semiconductor device adopting silicon as its material, advantageously.

A MOSFET (Metal Oxide Semiconductor Field Effect Transistor) employing silicon carbide has a dielectric breakdown resistance higher than that of a MOSFET employing silicon. Therefore, in the MOSFET employing silicon carbide, voltage applied to a gate insulating film is higher than that in the MOSFET employing silicon. For example, according to a silicon carbide MOSFET described in Japanese Patent Laying-Open No, 2010-245389, a well region is provided to project to a JFET (Junction Field Effect Transistor) region.

Moreover, a silicon carbide MOSFET described in Japanese Patent Laying-Open No. 2013-247252 has a structure in which hexagonal cells are arranged densely on the substrate, and has a coupling portion for coupling a corner portion of a p type layer of a certain cell and a corner portion of a p type layer of a cell adjacent to the foregoing cell to each other at a location below an n type reverse-implantation region.

### SUMMARY OF THE INVENTION

According to the silicon carbide MOSFET described in Japanese Patent Laying-Open No. 2010-245389, an electric field applied to the gate insulating film is relaxed to some extent. However, a distance from a location of overlapping of the apexes of the polygonal cells to a body region is longer than a distance from a location in the middle of two adjacent apexes to the body region. Therefore, it takes time for a depletion layer to sufficiently expand from the body region to the location of overlapping of the apexes of the polygonal cells, thus making it difficult to sufficiently relax an electric field applied to a portion of the gate insulating film on the location of overlapping of the apexes of the polygonal cells.

Moreover, according to the silicon carbide MOSFET described in Japanese Patent Laying-Open No. 2013-247252, a p type base region is formed by an epitaxial growth method. This results in a complicated manufacturing process for a silicon carbide MOSFET.

It is an object of one embodiment of the present invention to provide a method for manufacturing a silicon carbide semiconductor device to achieve relaxation of electric field concentration in a gate insulating film by way of a simple process.

A method for manufacturing a silicon carbide semiconductor device according to one embodiment of the present invention includes the following steps. A silicon carbide substrate having a main surface is prepared. A gate insulating film is formed on the main surface of the silicon carbide substrate. When viewed in a direction. perpendicular to the main surface, the silicon carbide substrate includes a first cell region and a second cell region each having an outer shape of polygon and sharing one side of the polygon. The first cell region has a first source region, a first body region, and a first drift region, the first source region having a first conductivity type, the first body region surrounding the first source region, the first body region having a second conductivity type different from the first conductivity type, the first body region having the outer shape of polygon when viewed in the direction perpendicular to the main surface, the first drift region having the first conductivity type, the first drift region being separated from the first source region by the first body region. The second cell region has a second source region, a second body region, and a second drift region, the second source region having the first conductivity type, the second body region surrounding the second source region, the second body region having the second conductivity type, the second body region having the outer shape of polygon when viewed in the direction perpendicular to the main surface, the second drift region having the first conductivity type, the second drift region being separated from the second source region by the second body region, the second drift region being connected to the first drift region at the one side of the polygon. When viewed in the direction perpendicular to the main surface, the silicon carbide substrate has a connection region provided to include an end portion of the one side, an apex of the first body region nearest to the end portion, and an apex of the second body region nearest to the end portion, the connection region being electrically connected to both the first body region and the second body region, the connection region having the second conductivity type. When viewed in a direction parallel to the main surface, the first drift region and the second drift region are provided between the gate insulating film and the connection region. In the step of forming the gate insulating film, the gate insulating film is formed on the main surface in contact with the first source region, the first body region, the first drift region, the second source region, the second body region, and the second drift region. The connection region, the first body region, and the second body region are formed by ion implantation.

The foregoing and other objects, features, aspects and advantages of the present invent on will become more apparent from the following detailed description of the present invention when taken in conjunction with the accompanying drawings.

### BRIEF DESCRIPTION OF THE DRAWINGS

FIG. 1 is a schematic longitudinal cross sectional view of a silicon carbide semiconductor device according to one embodiment of the present invention and corresponds to a cross sectional view taken along a folded line I-I of FIG. 3.

FIG. 2 is a schematic longitudinal cross sectional view of the silicon carbide semiconductor device according to the embodiment of the present invention, and corresponds to a cross sectional view taken along a line II-II of FIG. 3.

FIG. 3 is a schematic transverse cross sectional view showing a first example of a silicon carbide substrate of the silicon carbide semiconductor device according to the embodiment of the present invention, and corresponds to a cross sectional view taken along a line III-III of FIG. 1.

FIG. 4 is a schematic transverse cross sectional view showing the first example of the silicon carbide substrate of the silicon carbide semiconductor device according to the embodiment of the present invention with hatching being omitted, and corresponds to a cross sectional view taken along a line IV-IV of FIG. 1.

FIG. 5 is an enlarged view of a region V of FIG. 4.

FIG. 6 is a schematic transverse cross sectional view showing the first example of the silicon carbide substrate of the silicon carbide semiconductor device according to the embodiment of the present invention, and corresponds to a cross sectional view taken along a line IV-IV of FIG. 1.

FIG. 7 is a schematic transverse cross sectional view showing a second example of the silicon carbide substrate of the silicon carbide semiconductor device according to the embodiment of the present invention with hatching being omitted, and corresponds to a cross sectional view taken along line IV-IV of FIG. 1.

FIG. 8 is a schematic transverse cross sectional view showing the second example of the silicon carbide substrate of the silicon carbide semiconductor device according to the embodiment of the present invention, and corresponds to a cross sectional view taken along line IV-IV of FIG. 1.

FIG. 9 is a flowchart schematically showing a method for manufacturing the silicon carbide semiconductor device according to the embodiment of the present invention.

FIG. 10 is a schematic longitudinal cross sectional view schematically showing a first step of the method for manufacturing the silicon carbide semiconductor device according to the embodiment of the present invention.

FIG. 11 is a schematic transverse cross sectional view schematically showing a second step of the method for manufacturing the silicon carbide semiconductor device according to the embodiment of the present invention.

FIG. 12 is a schematic longitudinal cross sectional view schematically showing a second step of the method for manufacturing the silicon carbide semiconductor device according to the embodiment of the present invention, and corresponds to a cross sectional view (a) taken along a folded line XIIa-XIIa of FIG. 11 and a cross sectional view (b) taken along a line XIIb-XIIb of FIG. 11.

FIG. 13 is a schematic transverse cross sectional view schematically showing a third step of the method for manufacturing the silicon carbide semiconductor device according to the embodiment of the present invention.

FIG. 14 is a schematic longitudinal cross sectional view schematically showing the third step of the method for manufacturing the silicon carbide semiconductor device according to the embodiment of the present invention, and corresponds to a cross sectional view (a) taken along a folded line XIVa-XIVa of FIG. 13 and a cross sectional view (b) taken along a line XIVb-XIVb of FIG. 13.

FIG. 15 is a schematic longitudinal cross sectional view schematically showing a fourth step of the method for manufacturing the silicon carbide semiconductor device according to the embodiment of the present invention.

FIG. 16 is a schematic longitudinal cross sectional view schematically showing a fifth step of the method for manufacturing the silicon carbide semiconductor device according to the embodiment of the present invention.

FIG. 17 is a schematic transverse cross sectional view schematically showing a modification of the second step of the method for manufacturing the silicon carbide semiconductor device according to the embodiment of the present invention.

FIG. 18 is a schematic longitudinal cross sectional view schematically showing the modification a the second step of the method for manufacturing the silicon carbide semiconductor device according to the embodiment of the present invention, and corresponds to a cross sectional view (a) taken along a folded line XVIIIa-XVIIIa of FIG. 17 and across sectional view (b) taken along a line XVIIIb-XVIIIb of FIG. 17.

FIG. 19 is a schematic transverse cross sectional view schematically showing a modification of the third step of the method for manufacturing the silicon carbide semiconductor device according to the embodiment of the present invention.

FIG. 20 is a schematic longitudinal cross sectional view schematically showing a modification. of the third step of the method for manufacturing the silicon carbide semiconductor device according to the embodiment of the present invention, and corresponds to a cross sectional view (a) taken along a folded line XXa-XXa of FIG. 19 and a cross sectional view (b) taken along a line XXb-XXb of FIG. 19.

### DESCRIPTION OF THE PREFERRED EMBODIMENTS

### Description of Embodiments of the Present Invention

Next, embodiments of the present invention are listed and described.

(1) A method for manufacturing a silicon carbide semiconductor device 1 according to one embodiment of the present invention includes the following steps. A silicon carbide substrate 10 having a main surface 10a is prepared. A gate insulating film 15 is formed on main surface 10a of silicon carbide substrate 10. When viewed in a direction perpendicular to main surface 10a, silicon carbide substrate 10 includes a first cell region CL1 and a second cell region CL2 each having an outer shape of polygon and sharing one side M12 of the polygon. First cell region CL1 has a first source region 14a, a first body region 13a1, and a first drift region 12a1, first source region 14a, having a first conductivity type, first body region 13a1 surrounding first source region 14a, first body region 13a1 having a second conductivity type different from the first conductivity type, first body region 13a1 having the outer shape of polygon when viewed in the direction perpendicular to main surface 10a, first drift region 12a1 having the first conductivity type, first drift region 12a1 being separated from first source region 14a by first body region 13a1. Second cell region CL2 has a second source region 14b, a second body region 13b1, and a second drift region 12b1, second source region 14b having the first conductivity type, second body region 13b1 surrounding second source region 14b, second body region 13b1 having the second conductivity type, second body region 13b1 having the outer shape of polygon when viewed in the direction perpendicular to main surface 10a, second drift region 12b1 having the first conductivity type, second drift region 12b1 being separated from second source region 14b by second body region 13b1, second drift region 12b1 being connected to first drift region 12a1 at. the one side of the polygon. When viewed in the direction perpendicular to main surface 10a, silicon carbide substrate 10 has a connection region 17 provided to include an end portion C0 of the one side, an apex C1 of first body region 13a1 nearest to the end portion, and an apex C2 of second body region 13b1 nearest to the end portion, connection region 17 being electrically connected to both first body region 13a1 and second body region 13b1, connection region 17 having the second conductivity type. When viewed in a direction parallel to main surface 10a, first drift region 12a1 and second drift region 12b1 are provided between gate insulating film 15 and connection region 17. In the step of forming gate insulating film 15, gate insulating film 15 is formed on main surface 10a in contact with first source region 14a, first body region 13a1, first drift region 12a1, second source region 14b, second body region 13b1, and second drift region 12b1. Connection region 17, first body region 13a1 and second body region 13b1 are formed by ion implantation.

According to the method for manufacturing silicon carbide semiconductor device 1 according to (1), when viewed in the direction perpendicular to first main surface 10a, silicon carbide substrate 10 has connection region 17 provided to include end portion C0 of one side, apex C1 of first body region 13a1 nearest to the end portion, and apex C2 of second body region 13b1 nearest to the end portion, connection region 17 being electrically connected to both first body region 13a1 and second body region. 13b1, connection region 17 having second conductivity type. In this way, it is possible to sufficiently relax electric field applied to the portion of gate insulating film 15 above connection region 17. Moreover, connection region 17, first body region 13a1, and second body region 13b1 are formed by ion implantation. Accordingly, the silicon carbide semiconductor device can be manufactured by a process simpler than that in the case where connection region 17, first body region 13a1, and second body region 13b1 are formed by the epitaxial growth method. Furthermore, between gate insulating film 15 and connection region 17, first drift region 12a1 and second drift region 12b1 are provided. Accordingly, on resistance can be reduced as compared with a case where connection region 17 is in contact with Rate insulating film 15.

(2) Preferably in the method for manufacturing silicon carbide semiconductor device 1. according to (1), both first drift region 12a1 and second drift region 12b1 are formed by epitaxial growth. Accordingly, mobility can be made higher than that in the case where first drift region 12a1 and second drift region 12b1 are formed by ion implantation.

(3) Preferably in the method for manufacturing silicon carbide semiconductor device 1 according to (1) or (2), when viewed, from connection region 17, silicon carbide substrate 10 further includes a lower drift region 12a3, 12b3 located opposite to first drift region 12a1 and second drift region 12b1 and electrically connected to both first drift region 12a1 and second drift region 12b1. First drift region 12a1. second drift region 12b1, and the lower drift region are formed in the same epitaxial layer forming step. Accordingly, first drift region 12a1., second drift region 12b1, and the lower drift region can be formed by the simple method.

(4) Preferably in the method for manufacturing silicon carbide semiconductor device 1 according to an one of (1) to (3), when viewed in the direction perpendicular to the main surface, connection region 17 has a shape in conformity with an outer shape of polygon. Accordingly, an area of overlapping of gate insulating film 15 and connection region 17 becomes large, thereby effectively suppressing, a high electric field from being applied to gate insulating film 15.

(5) Preferably in the method for manufacturing silicon carbide semiconductor device 1 according to any one of (1) to (4), each of first drift region 12a1 and second drift region 12b1 has an impurity concentration of not more than 1×10¹⁶ cm⁻³. Accordingly, first drift region 12a1 and second. drift region 12b1 can be depleted effectively. As a result, a high electric field can be suppressed effectively from being applied to gate insulating film 15 formed on first drift region 12a1 and second drift region 12b1.

(6) Preferably in the method for manufacturing silicon carbide semiconductor device 1 according to any one of (1) to (5), the step of preparing silicon carbide substrate 10 includes steps of forming a silicon carbide epitaxial layer 12 having main surface 10a. and having the first conductivity type; forming connection region 17 provided to be spaced away from main surface 10a by performing ion implantation into main surface 10a; and forming first body region 13a1 and second body region 13b1 by performing ion implantation into main surface 10a, first body region 13a1 being electrically connected to connection region 17, second body region 13b1 being electrically connected to connection region 17. Accordingly, there can be provided a method for manufacturing silicon carbide semiconductor device 1 so as to attain relaxed electric field concentration in gate insulating film 15 with a simple process.

(7) Preferably in the method for manufacturing silicon carbide semiconductor device 1 according to any one of (1) to (5), the step of preparing silicon carbide substrate 10 includes steps of forming a silicon carbide epitaxial layer 12 having main surface 10a and having the first conductivity type; forming first body region 13a1 and second body region 13b1 by performing ion implantation into main surface 10a, first body region 13a1 being exposed at main surface 10a, second body region 13b1 being exposed at main surface 10a; and forming connection region 17 by performing ion implantation into main surface 10a, connection region 17 being electrically connected to both first body region 13a1 and second body region 13b1, connection region 17 being provided to be spaced away from main surface 10a. Accordingly, there can be provided a method for manufacturing silicon carbide semiconductor device 1 so as to attain relaxed electric field concentration in gate insulating film 15 with a simple process.

(8) Preferably in the method for manufacturing silicon carbide semiconductor device 1 according to (6) or (7), both first drift region 12a1 and second drift region 12b1 are formed by additionally performing ion implantation into main surface 10a of silicon carbide epitaxial layer 12. Accordingly, the impurity concentration in each of first drift region 12a1 and second drift region 12b1 can be made high, thereby attaining improved breakdown voltage of silicon carbide semiconductor device 1.

### Details of Embodiments of the Present Invention

The following describes an embodiment of the present invention with reference to figures. It should be noted that in the below-mentioned figures, the same or corresponding portions are given the same reference characters and are not described repeatedly. Regarding crystallographic indications in the present specification, an individual orientation is represented by [], a group orientation is represented by <>, and an individual plane is represented by ( ), and a group plane is represented by {}. In addition, a negative index is supposed to be crystallographically indicated by putting “−” (bar) above a numeral, but is indicated by putting the negative sign before the numeral in the present specification.

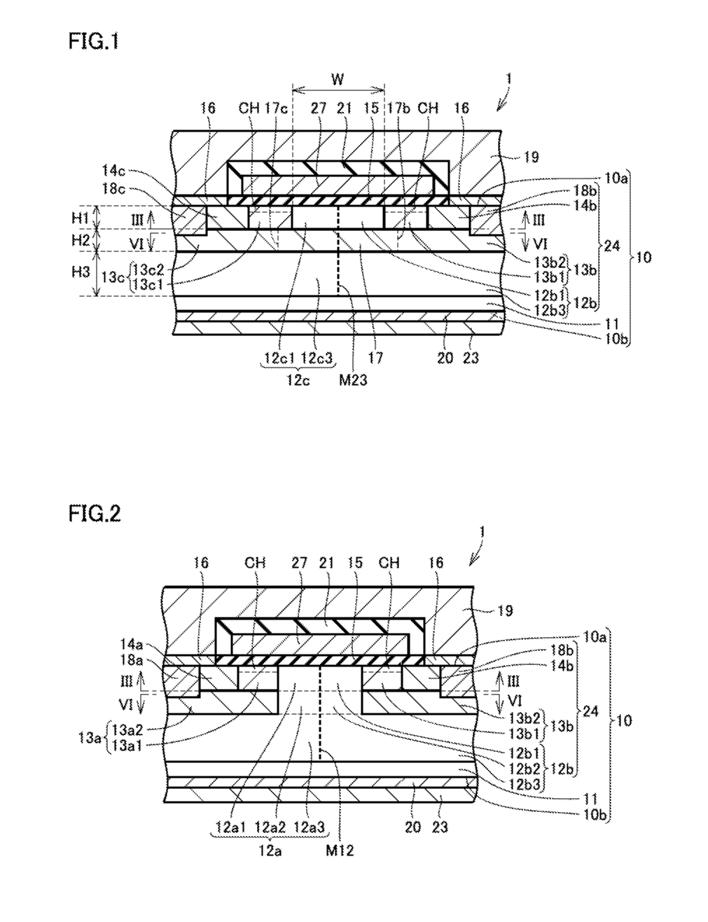

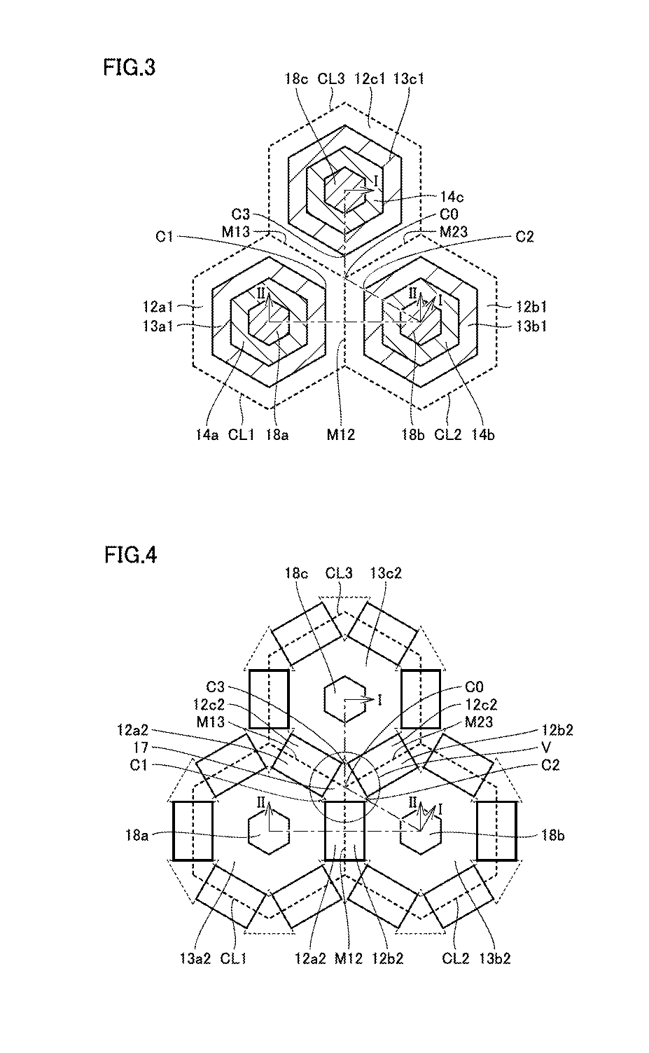

With reference to FIG. 1 to FIG. 8, the following describes a configuration of a MOSFET as one example of a silicon carbide semiconductor device 1 according to one embodiment of the present invention. FIG. 1 corresponds to a cross sectional view taken along a folded line I-I of FIG. 3. FIG. 2 corresponds to a cross sectional view taken along a line II-II of FIG. 3.

A MOSFET 1 according to the present embodiment mainly includes a silicon carbide substrate 10, a gate insulating film 15, a gate electrode 27, a source electrode 16, a drain electrode 20, an interlayer insulating film 21, an upper protecting electrode 19, and a lower protecting electrode 23.

Silicon carbide substrate 10 mainly includes a silicon carbide single crystal substrate 11 and a silicon carbide epitaxial layer 24 disposed on silicon carbide single crystal substrate 11. Silicon carbide single crystal substrate 11 is made of for example, a hexagonal silicon carbide single crystal having polytype 411, and has n type (first conductivity type) conductivity. Silicon carbide substrate 10 includes a first main surface 10a constituted of silicon carbide epitaxial layer 24, and a second main surface 10b located opposite to first main surface 10a. and constituted of silicon carbide single crystal substrate 11. First main surface 10a of silicon carbide substrate 10 corresponds to a plane angled off by, for example, about not more than 8° relative to a {0001} plane, and is preferably a plane angled off by about not more than 8° relative to a (0001) plane. Silicon carbide epitaxial layer 24 mainly has a drift region, a body region, a source region, a contact region, and a connection region 17.

The drift region has an n type impurity such as nitrogen (N), and has n type conductivity. The drift region includes an upper drift region, an intermediate drift region, and a lower drift region. With reference to FIG. 1 to FIG. 3, the upper drift region has a first upper drift region 12a1, a second upper drift region 12b1, and a third upper drift region 12c1. A total width W of second upper drift region 12b and third upper drift region 12c1 in a direction parallel to first main surface 10a is not less than 1.5 μm and not more than 4 μm, for example. With reference to FIG. 2 and FIG. 4, the intermediate drift region includes a first intermediate drift region 12a2, a second intermediate drift region 12b2, and a third intermediate drift region 12c2. With reference to FIG. 1 and FIG. 2, the lower drift region includes a first lower drift region 12a3, a second lower drift region 12b3, and a third lower drift region 12c3. The lower drift region has a thickness H3 of not less than 10 μm and not more than 300 μm, for example. Preferably, the concentration of the n type impurity such as nitrogen in each of first upper drift region 12a1 second upper drift region 12b1, and third upper drift region. 12c1 is not less than 1×10¹⁵ cm⁻³ and not more than 1×10¹⁶ cm⁻³. Preferably, the concentration of the n type impurity such as nitrogen in each of first intermediate drift region 12a2, second intermediate drift region 12b2, third intermediate drift region 12c2, first lower drift region 12a3, second lower drift region 12b3 and third lower drift region 12c3 is not less than 1×10¹⁴ cm ⁻³ and not more than 1×10¹⁶ cm⁻³. The concentration of the type impurity such as nitrogen in each of first upper drift region 12a1, second upper drift region 12b1, and third upper drift region 12c1 may be higher than the concentration of the n type impurity such as nitrogen in each of first intermediate drift region 12a2, second intermediate drift region 12b2, third intermediate drift region 12c2, first lower drift region 12a3, second lower drift region 12b3, and third lower drift region 12c3.

The body region contains a p impurity such as aluminum (Al) or boron (B), and has p type (second conductivity type) conductivity. With reference to FIG. 1 and FIG. 2, the body region mainly includes a first body region 13a, a second body region 13b, and a third body region 13c. With reference to FIG. 2, first body region 13a includes a first upper body region 13a1 and a first lower body region 13a2. With reference to FIG. 1 and FIG. 2, second body region 131) includes a second upper body region 13b1 and a second lower body region 13b2. With reference to FIG. 1, third body region 13c includes a third upper body region 13c1 and a third lower body region 13c2. The concentration of the p type impurity such as aluminum or boron in each of first lower body region 13a2, second lower body region 13b2, third lower body region 13c2, and connection region 17 is not less than 5×10¹⁷ cm⁻³ and not more than 1×10¹⁸ cm⁻³, for example. Each of first lower body region 13a2, second lower body region 13b2, third lower body region 13c2, and connection region 17 has a thickness H2 of not less than 0.3 μm and not more than 0.4 μm, for example. The concentration of the p type impurity such as aluminum or boron in each of First upper body region 13a1, second upper body region 13b1, and third upper body region 13c1 is not less than 1×10¹⁶ cm⁻³, and not more than 1×10¹⁸ cm⁻³, for example. Each of first upper body region 13a1, second upper body region 13b1, and third upper body region 13c1 has a thickness H1 of not less than 0.2 μm and not more than 0.8 μm, for example.

The source region contains an n type impurity such as phosphorus (P), and has n type conductivity type. With reference to FIG. 1 to FIG. 3, the source region mainly includes a first source region 14a, a second source region 14b, and a third source region 14c. The concentration of the n type impurity such as phosphorus in each of first source region 14a, second source region 14b, and third source region 14c is about 1×10²⁰ cm⁻³, for example. The source region is spaced away from the drift region by the body region. The concentration of the n type impurity such as phosphorus in the source region is higher than the concentration of the n type purity such as nitrogen in the drift region.

The contact region contains a p type impurity such as aluminum (Al) and has a p type conductivity type. The contact region mainly includes a first contact region 18a, a second contact region 18b, and a third contact region 18c. For example, the contact region contains an impurity such as Al, and has p type conductivity type. The concentration of the p type impurity such as aluminum in each of first contact region 18a, second contact region 18b, and third contact region 18c is about 1×10²⁰ cm⁻³, for example. The concentration of the p type impurity such as aluminum in the contact region is higher than the concentration of the p type impurity such as aluminum in the body region.

With reference to FIG. 3, when viewed in a plan view (field of view in a direction perpendicular to first main surface 10a), silicon carbide substrate 10 has a first cell region CL1, a second cell region CL2, and a third cell region CL3. Each of first cell region CL1, second cell region CL2, and third cell region CL3 has an outer shape of polygon. The polygon is, for example, a hexagon and is preferably a right hexagon. The polygon may be a quadrangle such as a rectangle or a square. When viewed in a plan view, first cell region CL1 is adjacent to second cell region CL2 and third cell region CL3. Second cell region CL2 is adjacent to first cell region CL1 and third cell region CL3. Third cell region CL3 is adjacent to first cell region CL1 and second cell region CL2.

First cell region CL1 and second cell region CL2 share a side M12. Second cell region CL2 and third cell region CL3 share a side M23. Third cell region CL3 and first cell region CL1 share a side M13. Side M12, side M23, and side M13 share a triple point C0. First upper drift region 12a1 is in contact with second upper drift region 12b1 at side M12. Second upper drift region 12b1 is in contact with third upper drift region 12cl at side M23. Third upper drift region 12c1 is in contact with first upper drift region 12a1 at side M13.

First cell region CL1 has first drift region 12a, first body region 13a, first source region 14a, and first contact region 18a. When viewed in a plan view, each of first body region 13a, first source region 14a, and first contact region 18a has an outer shape of hexagon. First contact region 18a is surrounded by first source region 14a. First source region 14a is surrounded by first upper body region 13a1. First upper body region 13a1 is surrounded by first upper drift region 12a1. First upper drift region 12a1 is separated from first source region 14a by first upper body region 13a1.

Second cell region CL2 has second drift region 12b, second body region 13b, second source region 14b, and second contact region 18b. When viewed in a plan view, each of second body region 13b, second source region 14b, and second contact region 18b has an outer shape of hexagon. Second contact region 18b is surrounded by second source region 14b. Second source region 14b is surrounded by second upper body region 13b1. Second upper body region 13b1 is surrounded by second upper drift region 12b1. Second upper drift region 12b1 is separated from second source region 14b by second upper body region 13b1.

Third cell region CL3 has third drift region 12c, third body region 13c, third source region 14c, and third contact region 18c. When viewed in a plan view, each of third body region 13c, third source region 14c, and third contact region 18c has an outer shape of hexagon. Third contact region 18c is surrounded by third source region 14c. Third source region 14c is surrounded by third upper body region 13c1. Third upper body region 13c1 is surrounded by third upper drift region 12c1. Third upper drift region 12c1 is separated from third source region 14c by third upper body region 13c1.

When viewed in a plan view, the outer shapes of first contact region 18a, second contact region 18b, and third contact region 18c may be analogous to the outer shapes of first source region 14a, second source region 14b, and third source region 14c, respectively. Similarly, when viewed in a plan view, the outer shapes of first source region 14a, second source region 14b, and third source region 14c may be analogous to the outer shapes of first body region 13a, second body region 13b, and third body region 13c, respectively.

Next, the following describes a configuration of connection region 17 with reference to FIG. 3 to FIG. 5. It should be noted that FIG. 4 is a diagram obtained by removing hatching from FIG. 6.

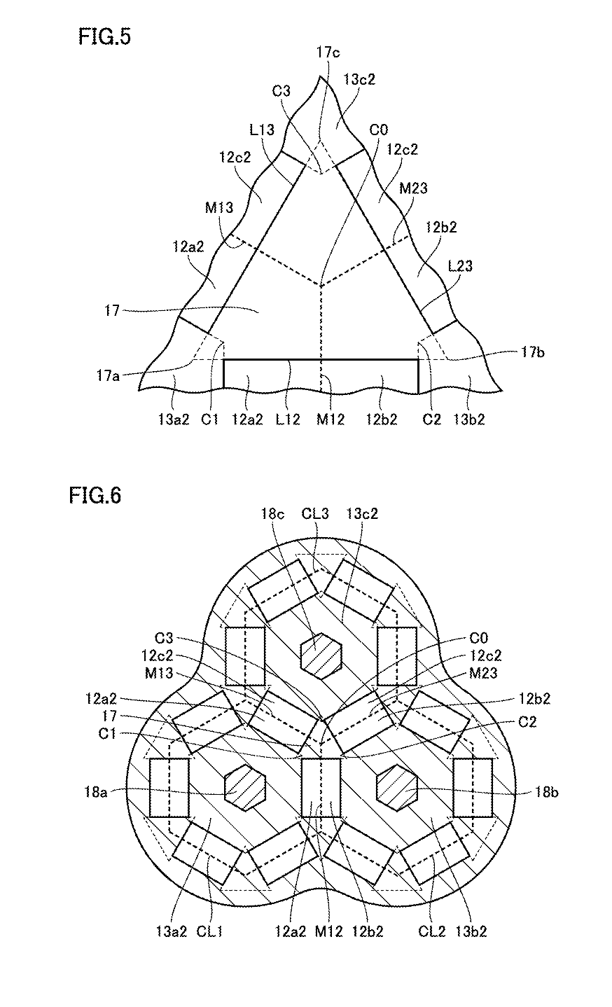

With reference to FIG. 3 to FIG. 5, first body region 13a has an apex C1, second body region 13b has an apex C2, and third body region 13c has an apex C3. When viewed in a plan view, connection region 17 is provided to include: end portion C0, which is the triple point on which the apexes of the three cell regions overlap with one another; apex C1 of first upper body region 13a1 nearest to end portion C0, apex C2 of second upper body region 13b1 nearest to end portion C0; and apex C3 of third upper body region 13c1 nearest to end portion C0. Connection region 17 is electrically connected to first upper body region 13a1, second upper body region 13b1, and third upper body region 13c1. Connection region 17 contains a p type impurity such as aluminum, and has p type conductivity. With reference to FIG. 1 and FIG. 5, connection region 17 preferably has an outer shape in conformity with a polygon (triangle) when viewed in a plan view. Connection region 17 may have an outer shape in conformity with a polygon other than the triangle, such as a quadrangle or a hexagon, for example. Connection region 17 is in contact with first intermediate drift region 12a2, second intermediate drift region 12b2, and third intermediate drift region 12c2.

With reference to FIG. 1, the upper surface of connection region 17 is in contact with second upper body region 13b1, second upper drift region 12b1, third upper body region 13c1, and third upper drift region 12c1. Connection region 17 has a lower surface in contact with second lower drift region 12b3 and third lower drift region 12c3. Connection region 17 has a side portion 17b in contact with second lower body region 13b2 and has a side portion 17c in contact with third lower body region 13c2. With reference to FIG. 1, FIG. 3, and FIG. 4, when viewed in a longitudinal cross section (field of view in the direction parallel to the first main surface), first upper drift region 12a1, second upper drift region 12b1, and third upper drift region 12c1 are provided between gate insulating film 15 and connection region 17.

With reference to FIG. 1 and FIG. 2, gate insulating film 15 is made of, for example, silicon dioxide and is provided on first main surface 10a of silicon carbide substrate 10. On first main surface 10a, gate insulating film 15 is in contact with the body region, the source region, and the drift region. Specifically, on first main surface 10a, gate insulating film 15 is in contact with first source region 14a, first upper body region 13a1, first upper drift region 12a1, second source region 14b, second upper body region 13b1, second upper drift region 12b1, third source region 14c, third upper body region 13c1, and third upper drift region 12c1. First upper body region 13a1, second upper body region 13b1, and third upper body region 13c1 each facing gate insulating film 15 are configured such that a channel region CH can be formed therein.

Gate electrode 27 is provided on gate insulating film 15. Gate insulating film 15 is provided to face channel region CH. Gate electrode 27 is provided to face first source region 14a, first upper body region 13a1, first upper drift region 12a1, second source region 14b, second upper body region 13b1, second upper drift region 12b1, third source region 14c, third upper body region 13c1, and third upper thin region 12c1. Gate electrode 27 is made of a conductor such as a polysilicon having an impurity added therein.

Interlayer insulating film 21 is provided to cover gate electrode 27. Interlayer insulating film 21 is made of silicon dioxide, for example. Interlayer insulating film 21 insulates gate electrode 27 and source electrode 16 from each other. Interlayer insulating film 21 is in contact with gate insulating film 15.

On first main surface 10a of silicon carbide substrate 10, source electrode 16 is in contact with first source region 14a, second source region 14b, and third source region 14c. Similarly, on first main surface 10a of silicon carbide substrate 10, source electrode 16 is in contact with first contact region 18a, second contact region 18b, and third contact region 18c. Source electrode 16 is made of a material containing aluminum, for example. Preferably, source electrode 16 is made of a material containing TiAlSi. Upper protecting electrode 19 is provided in contact with source electrode 16. Upper protecting electrode 19 is provided to cover interlayer insulating film 21.

Drain electrode 20 is provided in contact with second main surface 10b of silicon carbide substrate 10. Drain electrode 20 is made of a material, such as NiSi, capable of ohmic contact with silicon carbide single crystal substrate 11 of n type and is electrically connected to silicon carbide single crystal substrate 11. Lower protecting electrode 23 is provided in contact with drain electrode 20.

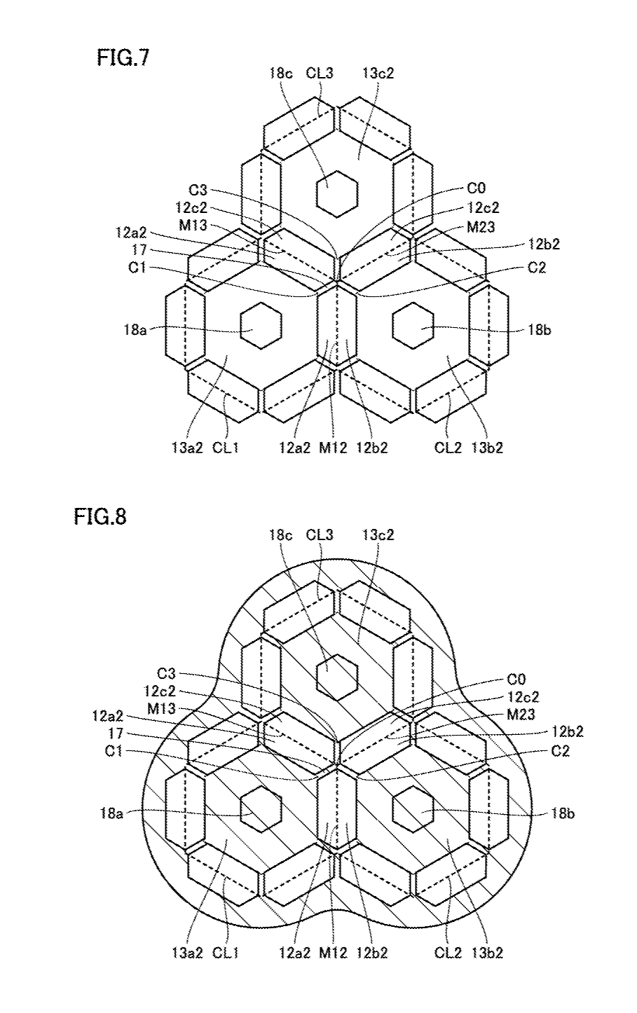

Next, the following describes a configuration of a modification of the connection region with reference to FIG. 7 and FIG. 8. FIG. 7 is a diagram obtained by removing hatching from FIG. 8.

Connection region 17 may be constituted of: a linear portion connecting end portion C0 that is the triple point and apex C1 of first upper body region 13a1 nearest to end portion C0 to each other; a linear portion connecting end portion C0 that is the triple point and apex C2 of second upper body region 13b1 nearest to end portion C0; and a linear portion connecting end portion C0 that is the triple point and apex C3 of third upper body region 13c1 nearest to end portion C0. In this case, a portion constituted of first intermediate drift region 12a2 and second intermediate drift region 12b2, a portion constituted of second intermediate drift region 12b2 and third intermediate drift region 12c2, and a portion constituted of first intermediate drift region 12a2 and third intermediate drift region 12c2 are hexagonal when viewed in a plan view.

When connection region 17 is constituted of the linear portion connecting end portion C0 that is the triple point and apex C1 of first upper body region 13a1 nearest to end portion C0 to each other, the linear portion connecting end portion C0 that is the triple point and apex C2 of second upper body region 13b1 nearest to end portion C0, and the linear portion connecting end portion C0 that is the triple point and apex C3 of third upper body region 13c1 nearest to end portion C0, a total area of first intermediate drift region 12a2, second intermediate drift region 12b2, and third intermediate drift region 12c2 when viewed in a plan view becomes larger than that in the case where connection region 17 is formed in conformity with the outer shape of triangle. Therefore, on resistance can be reduced.

Next, the following describes an operation of the MOSFET. With reference to FIG. 1 and FIG. 2, in a state where the voltage of gate electrode 27 is less than a threshold voltage, i.e., in an OFF state, a pn junction between the body region and the drift region just below gate insulating film 15 is reverse-biased, resulting, in a non-conductive state. On the other hand, when gate electrode 27 is fed with a voltage not less than the threshold voltage, an inversion layer is formed in channel region CH corresponding to gate insulating film 15. As a result, the source region and the drift region are electrically connected to each other, whereby a current flows between source electrode 16 and drain electrode 20.

Next, the following describes a method for manufacturing MOSFET 1 according to the present embodiment.

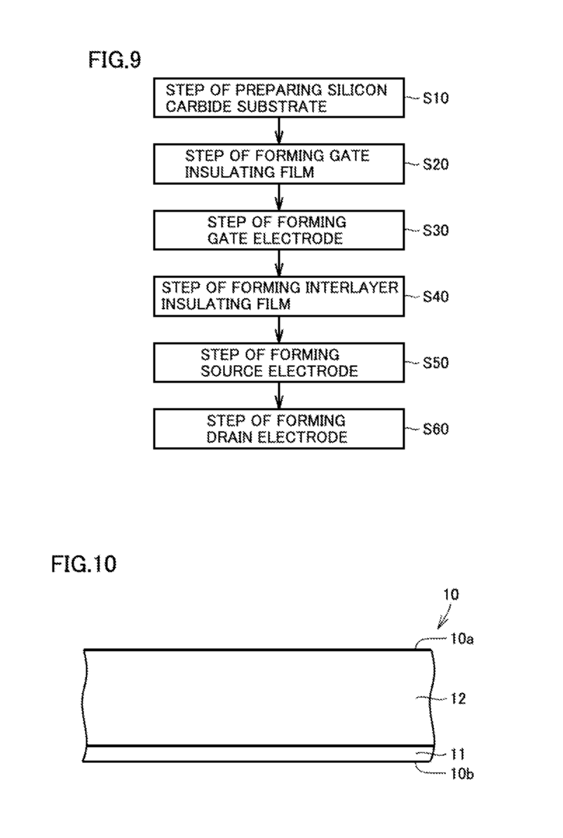

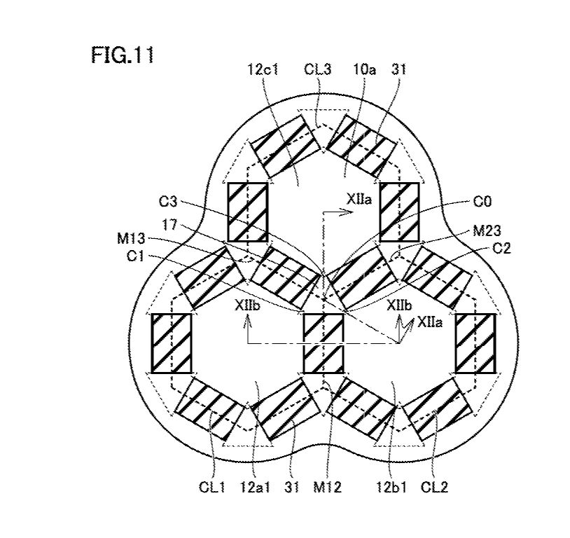

First, a step (S10: FIG. 9) of preparing a silicon carbide substrate is performed. Specifically, with reference to FIG. 10, silicon carbide single crystal substrate 11 made of hexagonal silicon carbide of polytype 4H is prepared, for example. Next, silicon carbide epitaxial layer 12 of n type (first conductivity type) is formed by epitaxial growth on silicon carbide single crystal substrate 11. Silicon carbide epitaxial layer 12 contains an n type impurity such as nitrogen (N), for example. Silicon carbide epitaxial layer 12 contains the n type impurity at a concentration of not more than 1×10¹⁶ cm⁻³. In this way, silicon carbide substrate 10 is prepared which has first main surface 10a and second main surface 10b opposite to first main surface 10a and has a type. Silicon carbide epitaxial layer 12 constitutes first main surface 10a. Silicon carbide single crystal substrate 11 constitutes second main surface 10b. First main surface 10a of silicon carbide substrate 10 may correspond to a plane angled off by about not more than 8° relative to the (0001) plane, for example. In this way, silicon carbide epitaxial layer 12 is formed which has first main surface 10a and has a type. Silicon carbide epitaxial layer 12 constitutes the drift region described later.

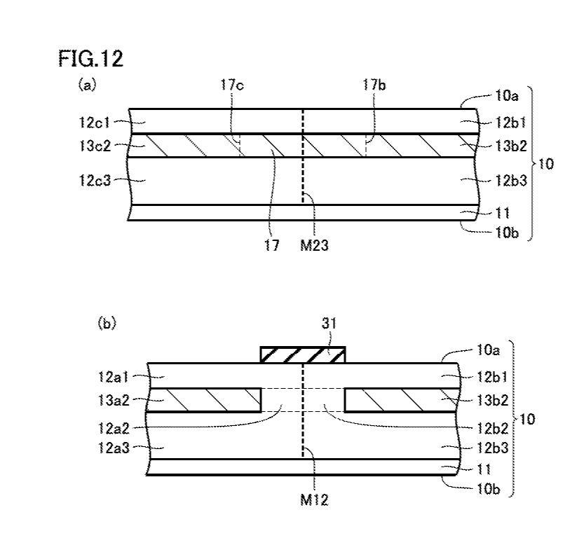

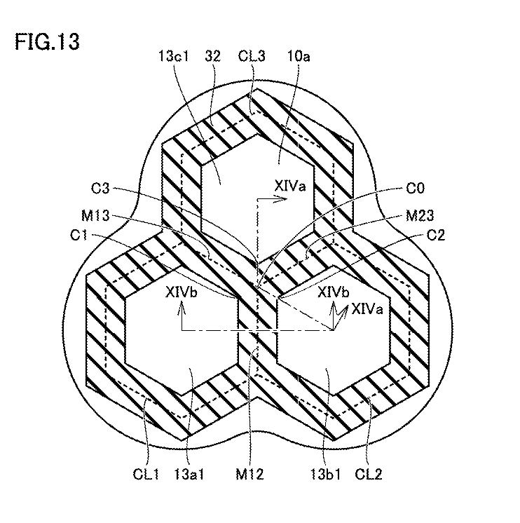

Next, a first mask layer forming step is performed. Specifically, with reference to FIG. 11 and FIG. 12, a first mask layer 31 is formed on first main surface 10a of silicon carbide epitaxial layer 12. FIG. 12 (a) is a cross sectional view taken along a folded line XIIa-XIIa of FIG. 11. FIG. 12 (b) is a cross sectional view taken along a line XIIb-XIIb of FIG. 11. First mask layer 31 is made of silicon dioxide, for example. With reference to FIG. 11, when viewed in a plan view, first mask layer 31 is formed on each side of first cell region CL1 in the form of hexagon, each side of second cell region CL2 in the form of hexagon, and each side of third cell region CL3 in the form of hexagon so as to be spaced away from the region in which each of first body region 13a, second body region 13b, and third body region 13c is formed, each apex of first cell region CL1 in the form of hexagon, each apex of second cell region CL2 in the form of hexagon, and each apex of third cell region CL3 in the form of hexagon. When viewed in a plan view, first mask layer 31 has a quadrangular shape.

Next, first mask layer 31 is used to implant, for example, aluminum ions into silicon carbide epitaxial layer 12. Accordingly, first lower body region 13a2, second lower body region 13b2, third lower body region 13c2, and connection region 17 are formed. That is, first lower body region 13a2, second lower body region 13b2, third lower body region 13c2, and connection region 17 are formed by the ion implantation. With reference to FIG. 12 (a) and FIG. 12 (b), first lower body region 13a2, second lower body region 13b2, third lower body region 13c2, and connection region 17 are formed between first main surface 10a and second main surface 10b so as to be spaced away from first main surface 10a and second main surface 10b. With reference to FIG. 12 (a), connection region 17 is in contact with second lower body region 13b2 at side portion 17b and is in contact with third lower body region 13c2 at side portion 17c. A region between second lower body region 13b2 and silicon carbide single crystal substrate 11 serves as second lower drift region 12b3 and a region between third lower body region 13c2 and silicon carbide single crystal substrate 11 serves as third lower drift region 12c3. With reference to FIG. 12 (b), a region between side M12 and second lower body region 13b2 serves as second intermediate drift region 12b2, and a region between side M12 and first lower body region 13a2 serves as first intermediate drift region 12a2. Next, first mask layer 31 is removed from first main surface 10a. By performing ion implantation into first main surface 10a of silicon carbide epitaxial layer 12 as described above, connection region 17 is formed to be spaced away from first main surface 10a.

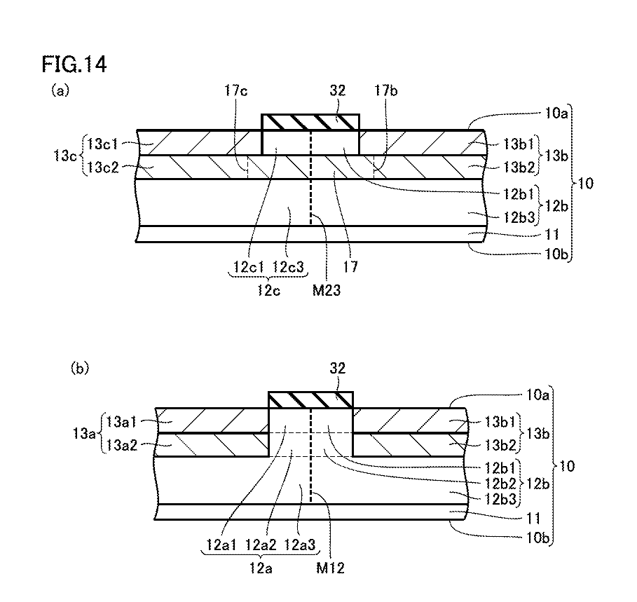

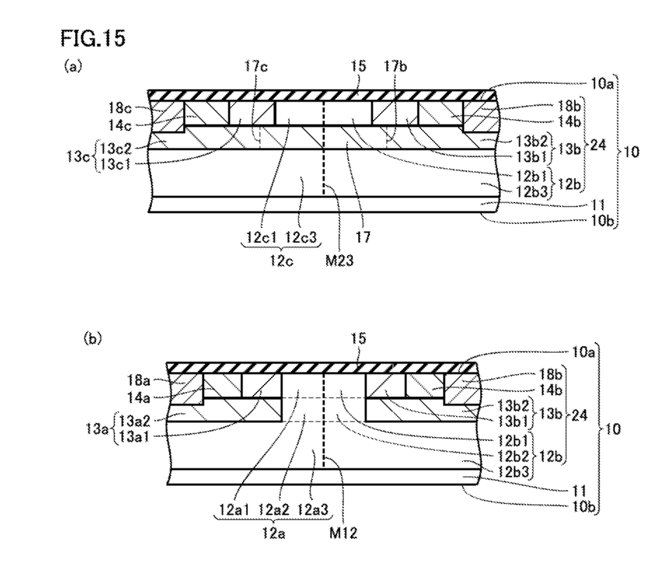

Next, a second mask layer forming step is performed. Specifically, with reference to FIG. 13 and FIG. 14, second mask layer 32 is formed on first main surface 10a of silicon carbide epitaxial layer 12. FIG. 14 (a) is a cross sectional view taken along a folded line XIVa-XIVa of FIG. 13. FIG. 14 (b) is a cross sectional view taken along a line XIVb-XIVb of FIG. 13. Second mask layer 32 is made of silicon dioxide, for example. With reference to FIG. 13, when viewed in a plan view, second mask layer 32 has hexagonal openings above regions in which first body region 13a, second body region 13b, and third body region 13c are to be formed. Second mask layer 32 is formed on each side of first cell region CL1 in the form of hexagon, each side of second cell region CL2 in the form of hexagon, and each side of third cell region CL3 in the form of hexagon. When viewed in a plan view, second mask layer 32 has a honeycomb structure.

Next, second mask layer 32 is used to implant, for example, aluminum ions into first main surface 10a of silicon carbide epitaxial layer 12, thereby forming first upper body region 13a1 second upper body region 13b1 and third upper body region 13c1. First upper body region 13a1 is formed to be electrically connected to connection region 17 and first lower body region 13a2. Second upper body region 13b1 is formed to be electrically connected to connection region 17 and second lower body region 13b2. Third upper body region 13c1 is formed to be electrically connected to connection region 17 and third lower body region 13c2. With reference to FIG. 14 (a), second upper body region 13b1 is formed in contact with second lower body region 13b2. Third upper body region 13c1 is formed in contact with third lower body region 13c2. A region among second upper body region 13b1, third upper body region 13c1, and connection region 17 serve as second upper drift region 12b1 and third upper drift region 12c1. That is, each of first upper drift region 12a1, second upper drift region 12b1 and third upper drift region 12c1 is formed between first main surface 10a and connection region 17. With reference to FIG. 14 (b), first upper body region 13a1 is formed in contact with first lower body region 13a2. A region between side M12 and second upper body region 13b1. serves as second upper drift region 12b1, and a region between side M12 and first upper body region 13a1 serves as first upper drift region 12a1. Next, second mask layer 32 is removed from first main surface 10a.

It should be noted that first upper drift region 12a1, second upper drift region. 12b1, and third upper drift region 12c1 may be formed by additionally performing ion implantation of an n type impurity such as nitrogen into first main surface 10a of silicon carbide epitaxial layer 12 having n type conductivity type. In this case, the concentration of the n type impurity such as nitrogen in each of first upper drift region 12a1, second upper drift region 12b1, and third upper drift region 12c1 is higher than the concentration of the n type impurity such as nitrogen in each of first intermediate drift region 12a2, second intermediate drift region 12b2, third intermediate drift region 12c2, first lower drift region 12a3, second lower drift region 12b3, and third lower drift region 12c3, The concentration of the n type impurity such as nitrogen in each of first upper drift region 12a1, second upper drift region 12b1, and third upper drift region. 12c1 is not more than 1×10¹⁶ cm⁻³.

Next, a source region forming step is performed. For example, a third mask layer (not shown) is formed on first main surface 10a of silicon carbide substrate 10. The third mask layer has openings in conformity with regions in which first source region 14a, second source region 14b, and third source region 14c are to be formed. Next, the third mask layer is used to implant, for example, phosphorous ions into each of first body region 13a, second body region 13b, and third body region 13c. Accordingly, there are formed :first source region 14a surrounded by first body region 13a, second source region 14b surrounded by second body region 13b, and third source region 14c surrounded by third body region 13c. Next, the third mask layer is removed from first main surface 10a.

Next, a contact region forming step is performed. For example, a fourth mask layer (not shown) is formed on first main surface 10a of silicon carbide substrate 10. The fourth mask layer has openings in conformity with regions in which first contact region 18a, second contact region 18b, and third contact region 18c are to be formed. Next, the fourth mask layer is used to implant, for example, aluminum ions into first source region 14a, second source region 14b, and third source region 14c. Accordingly, there are formed first contact region 18a surrounded by first source region 14a, second contact region 18b surrounded by second source region 14b, and third contact region 18c surrounded by third source region 14c. Next, the fourth mask layer is removed from first main surface 10a.

Next, an activation annealing step is performed. Specifically, for example, in an inert gas atmosphere such as argon or the like, a heat treatment is performed such that silicon carbide substrate 10 is heated at about 1700° C. and is held for about 30 minutes, for example. Accordingly, the impurities introduced by the ion implantations are activated.

In this way, silicon carbide substrate 10 having first main surface 10a is prepared. With reference to FIG. 3, when viewed in the direction perpendicular to first main surface 10a, silicon carbide substrate 10 has first cell region CL1, second cell region CL2, and third cell region CL3. Each of first cell region CL1, second cell region CL2, and third cell region CL3 has the outer shape of polygon. The polygon is, for example, a hexagon and is preferably a right hexagon. The polygon may be a quadrangle such as a rectangle or a square. When viewed in a plan view, first cell region CL1 is adjacent to second cell region CL2 and third cell region CL3. Second cell region CL2 is adjacent to first cell region CL1 and third cell region CL3. Third cell region CL3 is adjacent to first cell region CL1 and second cell region CL2.

First cell region CL1 and second cell region CL2 share side M12. Second cell region CL2 and third cell region CL3 share side M23. Third cell region CL3 and first cell region CL1 share side M13. Side M12, side M23, and side M13 share triple point C0. First upper drift region 12a1 is in contact with second upper drift region 12b1 at side M12. Second upper drift region 12b1 is in contact with third upper drift region 12c1 at side M23. Third upper drift region 12c1 is in contact with first upper drift region 12a1 at side M13.

First cell region CL1 includes: first source region 14a that has n type; first upper body region 13a1 that surrounds first source region 14a, that has p type different from n type, and that has an outer shape of polygon when viewed in the direction perpendicular to first main surface 10a; and first upper drift region 12a1 that has n type and that is separated from first source region 14a by first upper body region 13a1.

Second cell region CL2 includes: second source region 14b that has n type; second upper body region 13b1 that surrounds second source region 14b, that has p type, and that has an outer shape of polygon when viewed in the direction perpendicular to first main surface 10a; and second upper drift region 12b1 that has n type, that is separated from second source region 14b by second upper body region 13b1, and that is connected to first upper drift region 12a1 at side M12 of the polygon.

Third cell region CL3 includes: third source region 14c that has n type; third upper body region 13c1 that surrounds third source region 14c, that has p type, and that has an outer shape of polygon when viewed in the direction perpendicular to first main surface 10a; and third upper drift region 12c1 that has n type and that is separated from third source region 14c by third upper body region 13c1.

With reference to FIG. 3 to FIG. 6, when viewed in the direction perpendicular to first main surface 10a, silicon carbide substrate 10 includes connection region 17 provided to include end portion C0 of side M12, apex C1 of first upper body region 13a1 nearest to end portion C0, apex C2 of second upper body region 13b1 nearest to end portion C0, and apex C3 of third upper body region 13c1 nearest to end portion C0, connection region 17 being electrically connected to first upper body region 13a1, second upper body region 13b1, and third upper body region 13c1, connection region 17 having p type. When viewed in the direction parallel to first main surface 10a, first upper drift region 12a1, second upper drift region 12b1, and third upper drift region 12c1 are provided between gate insulating film 15 and connection region 17. Preferably, when viewed in the direction perpendicular to first main surface 10a, connection region 17 has a shape in conformity with an outer shape of polygon. In the present embodiment, connection region 17 has a shape in conformity with an outer shape of triangle.

The drift region includes the upper drift region, the intermediate drift region, and the lower drift region. The upper drift region includes first upper drift region 12a1, second upper drift region 12b1, and third upper drift region 12c1. The intermediate drift region includes first intermediate drift region 12a2, second intermediate drift region 12b2, and third intermediate drift region 12c2. The lower drift region has first lower drift region 12a3, second lower drift region 12b3, and third lower drift region 12c3. First upper drift region 12a1, second upper drift region 12b1, third upper drift region 12c1, first intermediate drift region 12a2, second intermediate drift region 12b2, third intermediate drift region 12c2, first lower drift region 12a3 second lower drift region 12b3, and third lower drift region 12c3 are formed by epitaxial growth in the step of forming silicon carbide epitaxial layer 12. In order to suppress introduction of defects, it is desirable to perform no ion implantation into the drift region.

When viewed from connection region 17, the lower drift region is located opposite to the upper drift region and is electrically connected to the upper drift region via the intermediate drift region. More specifically, when viewed from connection region 17, first lower drift region 12a3 is located opposite to first upper drift region 12a1, and is connected to first upper drift region 12a1 via first intermediate drift region 12a2. Likewise, when viewed from connection region 17, second lower drift region 12b3 is located opposite to second upper drift region 12b1, and is connected to second upper drift region 12b1 via second intermediate drift region 12b2. Likewise, when viewed from connection region 17, third lower drift region 12c3 is located opposite to third upper drift region 12c1, and is connected to third upper drift region 12c1 via third intermediate drift region 12c2. The upper drift region, the intermediate drift region, and the lower drift region are formed by the same epitaxial layer forming step. More specifically, first upper drift region 12a1, second upper drift region 12b1, third upper drift region 12c1, first intermediate drift region 12a2, second intermediate drift region 12b2, third intermediate drift region 12c2, first lower drift region 12a3, second lower drift region 12b3, and third lower drift region 12c3 are formed by the same epitaxial growth step in the above-described step of forming silicon carbide epitaxial layer 12.

Preferably, the concentration of the n type impurity such as nitrogen in the upper drift region is not less than 1×10¹⁵ cm⁻³ and not more than 1×10¹⁶ cm⁻³. More specifically, the concentration of the n type impurity such as nitrogen in each of first upper drift region 12a1, second upper drift region 12b1, and third upper drift region 12c1 is not less than 1×10¹⁵ cm⁻³and not more than 1×10¹⁶ cm⁻³. The concentration of the n type impurity such as nitrogen in each of the intermediate drift region and the lower drift region is, for example, not less than 1×10¹⁴ cm⁻³ and not more than 1×10¹⁶ cm⁻³.

The concentration of the p type impurity such as aluminum or boron in each of first lower body region 13a2, second lower body region 13b2, third lower body region 13c2, and connection region 17 is, for example, not less than 5×10¹⁷ cm⁻³ and not more than 1×10¹⁸ cm⁻³. Thickness H2 of each of first lower body region 13a2, second lower body region 13b2, and third lower body region 13c2 is not less than 0.3 μm and not more than 0.4 μm, for example. The concentration of the p type impurity such as aluminum or boron in each of first upper body region 13a1, second upper body region 13b1, and third upper body region 13c1 is, for example, not less than 1×10¹⁶ cm⁻³ and not more than 1×10¹⁸ cm⁻³. Thickness H1 of each of first upper body region 13a1, second upper body region 13b1, and third upper body region 13c1 is not less than 0.2 μm and not more than 0.8 μm, for example.

Next, a step (S20: FIG. 9) of forming the gate insulating film is performed. With reference to FIG. 15 (a) and FIG. 15 (b), gate insulating film 15 is formed in contact with first main surface 10a of silicon carbide epitaxial layer 12. Specifically, in an oxygen environment, a heat treatment is performed such that silicon carbide substrate 10 is heated at about 1300° C. and is held, for about 1 hour, for example. Accordingly, on first main surface 10a of silicon carbide substrate 10, gate insulating film 15 is formed in contact with first source region 14a, first upper body region 13a1, first upper drift region 12a1, second source region 14b, second upper body region 13b1, second upper drift region 12b1, third source region 14c, third upper body region 13c1, and third upper drift region 12c1. Between connection region 17 and gate insulating. film 15, first upper drift region 12a1, second upper drift region 12b1, and third upper drift region 12c1 are disposed.

Next, a nitrogen annealing step may be performed. Specifically, in a nitrogen monoxide atmosphere, silicon carbide substrate 10 is held for about 1 hour at a temperature of about 1100° C., for example. Next, in an inert gas such as argon or nitrogen, a heat treatment may be performed to heat silicon carbide substrate 10. For example, in an argon atmosphere, silicon carbide substrate 10 is held for about 1 hour at a temperature of not less than 1100° C. and not more than 1500° C.

Next, a step (S30: FIG. 9) of forming the gate electrode is performed. For example, a CVD (Chemical Vapor Deposition) method, photolithography, and etching are employed to form, on gate insulating film 15, gate electrode 27 made of polysilicon having an impurity added therein at a high concentration to serve as a conductor. When viewed in a plan view, gate electrode 27 is formed to face first source region 14a, first upper body region 13a1, first upper drift region 12a1, second source region 14b, second upper body region 13b1, second upper drift region 12b1, third source region 14c, third upper body region 13c1, and third upper drift region 12c1. When viewed in a plan view, gate electrode 27 is formed to overlap with first upper drift. region 12a1, second upper drift region 12b1, third upper drift region 12c1, and connection region 17. Preferably, when viewed in a plan view, gate electrode 27 is formed to entirely cover the surface of connection region 17.

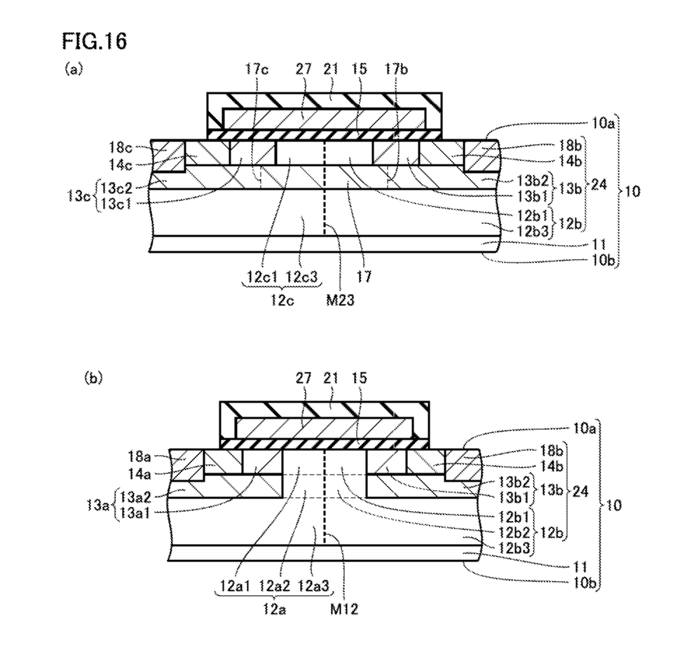

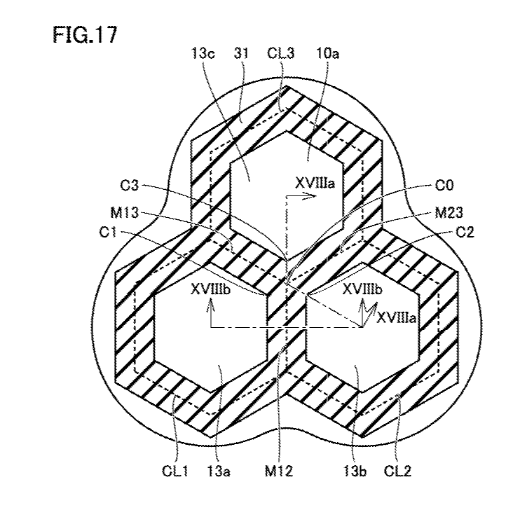

Next, a step (S40: FIG. 9) of forming the interlayer insulating film is performed. For example, by the CVD method, interlayer insulating film 21 is formed to cover gate electrode 27. Interlayer insulating film 21 is formed in contact with both gate electrode 27 and gate insulating film 15. interlayer insulating film 21 is made of silicon dioxide, which is an insulator, for example. Next, photolithography and etching are employed to remove interlayer insulating film 21 and gate insulating film 15 from a region in which the source electrode is to be formed. Accordingly, as shown in FIG. 16 (a) and FIG. 16 (b), first contact region 18a, second contact region 18b, third contact region. 18c, first source region 14a, second source region 14b, and third source region 14c are exposed through gate insulating film 15.

Next, a step (S50: FIG. 9) of forming the source electrode is performed. For example, a sputtering method is employed to form source electrode 16 in contact with both the source region and the contact region, Source electrode 16 may contain Ti (titanium) atoms, Al (aluminum) atoms, and Si (silicon) atoms, for example. After the formation of source electrode 16, source electrode 16 is heated at about 1000° C., for example. Accordingly, source electrode 16 thus heated is silicided to make ohmic contact with the source region having n type conductivity. Preferably, source electrode 16 makes ohmic contact with the contact region having p type conductivity. Next, for example, upper protecting electrode 19 containing aluminum is formed in contact with source electrode 16.

Next, a step (S60: FIG. 9) of forming the drain electrode is performed. For example, the sputtering method is employed to form drain electrode 20 in contact with second main surface 10b of silicon carbide single crystal substrate 11. Drain electrode 20 contains NiSi for example. Drain electrode 20 makes ohmic contact with silicon carbide single crystal substrate 11 having n type conductivity. Next, lower protecting electrode 23 is formed in contact with drain electrode 20. With the above procedure, MOSFET 1 shown in FIG. 1 to FIG. 6 is completed.

Next, the following describes a method for manufacturing silicon carbide substrate 10 according to the modification of the embodiment.

First, by performing the above-described silicon carbide substrate preparing step (S10: FIG. 9), silicon carbide substrate 10 having first main surface 10a and second main surface 10b is prepared. Silicon carbide epitaxial layer 12 has n type conductivity, and constitutes first main surface 10a of silicon carbide substrate 10. Silicon carbide single crystal substrate 11 has n type conductivity, and constitutes second main surface 10b of silicon carbide substrate 10.

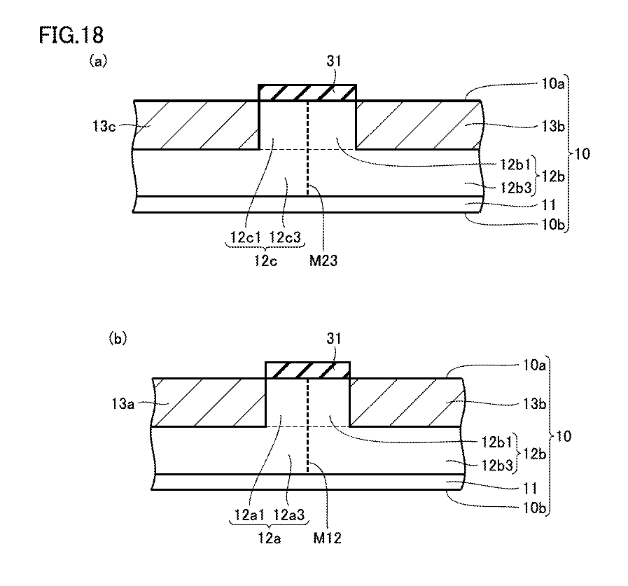

Next, the first mask layer thrilling step is performed. Specifically, with reference to FIG. 17 and FIG. 18, first mask layer 31 is formed on first main surface 10a of silicon carbide epitaxial layer 12. FIG. 18 (a) is a cross sectional view taken along a folded line XVIIIa-XVIIIa of FIG. 17. FIG. 18 (b) is a cross sectional view taken along a line XVIIIb-XVIIIb of FIG. 17. First mask layer 31 is made of silicon dioxide, for example. With reference to FIG. 17, when viewed in a plan view, first mask layer 31 has hexagonal openings above regions in which first body region 13a, second body region 13b, and third body region 13c are to be formed. First mask layer 31 is formed on each side of first cell region CL1 in the form of hexagon, each side of second cell region CL2 in the form of hexagon, and each side of third cell region CL3 in the form of hexagon. When viewed in a plan view, first mask layer 31 has a honeycomb structure.

Next, first mask layer 31 is used to implant, for example, aluminum ions into silicon carbide epitaxial layer 12. Accordingly, first body region 13a, second body region 13b, and third body region 13c are formed. That is, first body region 13a, second body region 13b, and third body region 13c are formed by ion implantation. With reference to FIG. 18 (a) and FIG. 18 (b), first body region 13a, second body region. 13b, and third body region 13c are formed to be exposed at first main surface 10a of silicon carbide epitaxial layer 12. A region between first body region 13a and silicon carbide single crystal substrate 11 serves as first lower drift region 12a3. Similarly, a region between second body region 13b and silicon carbide single crystal substrate 11 serves as second lower drift region 12b3. Similarly, a region between third body region 13c and silicon carbide single crystal substrate 11 serves as third lower drift region 12c3. A region between side M12 and second upper body region 13b serves as second upper drift region 12b1, and a region between side M12 and first upper body region 13a serves as first upper drift region 12a1. Similarly, a region between side M23 and second body region 13b serves as second upper drift region 12b1, and a region between side M23 and third body region 13c serves as third upper drift region 12c1. Next, first mask layer 31 is removed from first main surface 10a. By performing the ion implantation into first main surface 10a of silicon carbide epitaxial layer 12 as described above, first upper body region 13a1 is formed to be exposed at first main surface 10a, second upper body region 13b1 is formed to be exposed at first main surface 10a, and third upper body region 13c1 is formed to be exposed at first main surface 10a.

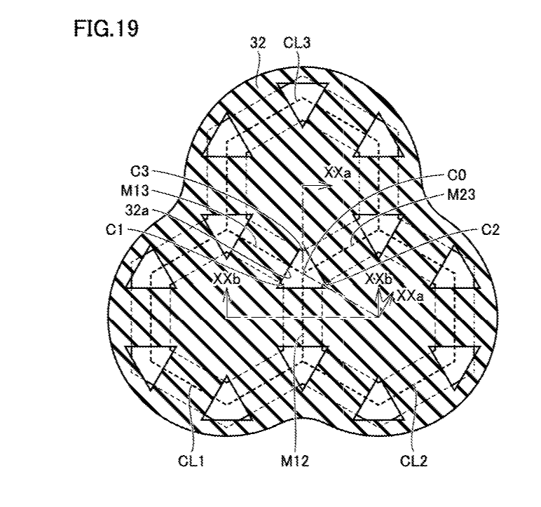

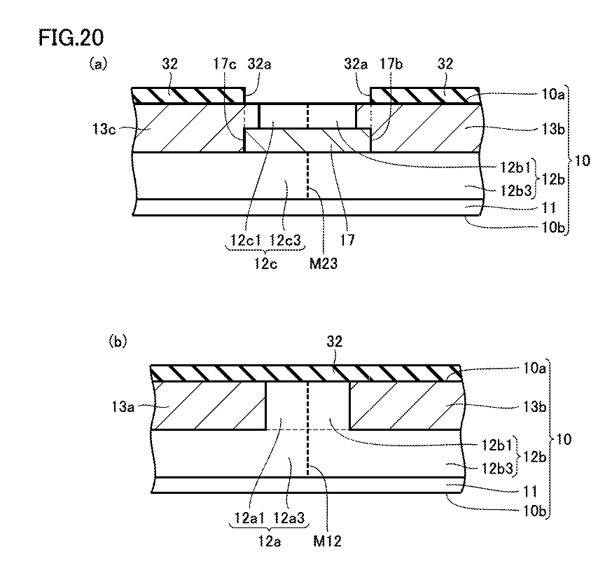

Next, a second mask layer forming step is performed. Specifically, with reference to FIG. 19 and FIG. 20, second mask layer 32 is formed on first main surface 10a of silicon carbide epitaxial layer 12. FIG. 20 (a) is a cross sectional view taken along a folded line XXa-XXa of FIG. 19. FIG. 20 (b) is a cross sectional view taken along a line XXb-XXb of FIG. 19. Second mask layer 32 is made of silicon dioxide, for example. With reference to FIG. 19, when viewed in a plan view, second mask layer 32 has triangular openings. in conformity with regions in each of which connection region 17 is to be formed. Second mask layer 32 has openings above each apex of first cell region CL1 in the form of hexagon, each apex of second cell region CL2 in the form of hexagon, each apex of third cell region CL3 in the form of hexagon, each apex of first body region 13a in the form of hexagon, each apex of second body region 13b in the form of hexagon, and each apex of third body region 13c. in the form of hexagon. The respective shapes of openings formed above two adjacent apexes are triangular, one triangle has a shape obtained by rotating the other triangle by 180° about a straight line perpendicular to first main surface 10a. On first main surface 10a, second mask layer 32 is in contact with first body region 13a, second body region 13b, third body region 13c, first upper drift region 12a1, second upper drift region 12b1, and third upper drift region 12c1.

Next, second mask layer 32 is used to implant, for example, aluminum ions into first main surface 10a of silicon carbide epitaxial layer 12, thereby forming connection region 17. Connection region 17 is electrically connected to first body region 13a, second body region 13b, and third body region 13c. Connection region 17 is provided to be spaced away from first main surface 10a. When viewed in a plan view, connection region 17 may be formed to overlap with a portion of first body region 13a, a portion of second body region 13b, mid a portion of third body region 13c. The concentration of the p type impurity in the portion of connection region 17 formed to overlap with the body region is higher than the concentration of the p type impurity in the portion of the connection region formed not to overlap with the body region. As shown in FIG. 20 (a), connection region 17 is formed such that first upper drift region 12a1, second upper drift region 12b1, third upper drift region 12c1, the portion of first body region 13a, the portion of second body region 13b, and the portion of third body region 13c are disposed between connection region 17 and first main surface 10a. By performing the ion implantation into first main surface 10a as described above, connection region 17 may be formed to be electrically connected to first body region 13a, second body region 13b, and third body region 13c, and may be provided to be spaced away from first main surface 10a.

It should be noted that first upper drift. region 12a1, second upper drift region 12b1, and third upper drift region 12c1 may be formed by additionally performing ion implantation of an n type impurity such as nitrogen into first main surface 10a of silicon carbide epitaxial layer 12 having n type conductivity type. In this case, the concentration of the n type impurity such as nitrogen in each of first upper drift region 12a1, second upper drift region 12b1, and third upper drift region 12c1 is higher than the concentration of the n type impurity such as nitrogen in each of first intermediate drift region 12a2, second intermediate drift region 12b2, third intermediate drift region 12c2 first lower drift region 12a3, second lower drift region 12b 3, and third lower drift region 12c3. The concentration of the n type impurity such as nitrogen in each of first upper drift region 12a1, second upper drift region 12b1, and third upper drift region. 12c1 is not more than 1×10¹⁶ cm⁻³.

Next, the source region forming step, the contact region forming step, and the activation annealing step are performed, thereby preparing silicon carbide substrate 10 according to the modification. Next, the step of forming the gate insulating film (S20: FIG. 9), the step of forming the gate electrode (S30: FIG. 9), the step of forming the interlayer insulating film (S40: FIG. 9), the step of forming the source electrode (S50: FIG. 9) the step of forming the drain electrode (S60: FIG. 9), and the like are performed, thereby manufacturing the MOSFET according to the modification of the embodiment.

Although it has been illustrated that the first conductivity type is n type and the second conductivity type is p type in the above-mentioned embodiment, the first conductivity type may be p type and the second conductivity type may be n type. Although the MOSFET has been described as an exemplary silicon carbide semiconductor device, the silicon carbide semiconductor device may be an IGBT (insulated Gate Bipolar Transistor) or the like.

Next, the following describes function and effect of the method for manufacturing MOSFET 1 serving as the silicon carbide semiconductor device according to the present embodiment.

According to the method for manufacturing MOSFET 1 according to the present embodiment, when viewed in the direction perpendicular to first main surface 10a, silicon carbide substrate 10 has connection region 17 provided to include end portion C0 of one side, apex C1 of first upper body region 13a1 nearest to the end portion, and apex C2 of second upper body region 13b1 nearest to the end portion, connection region 17 being electrically connected to both first upper body region 13a1 and second upper body region 13b1, connection region 17 having p type. in this way, it is possible to sufficiently relax electric field applied Co the portion of gate insulating film 15 above connection region 17. Moreover, connection region 17, first upper body region 13a1, and second upper body region 13b1 are formed by ion implantation. Accordingly, MOSFET 1 can be manufactured by a process simpler than that in the case where connection region 17, first upper body region 13a1, and second upper body region 13b1 are formed by the epitaxial growth method. Furthermore, between gate insulating film 15 and connection regions 17, first upper drift region 12a1 and second upper drift region 12b1 are provided. Accordingly, on resistance can be reduced as compared with a case where connection region 17 is in contact with gate insulating film 15.

Moreover, according to the method for manufacturing MOSFET 1 according to the present embodiment, both. first upper drift region 12a1 and second upper drift region 12b1 are formed by epitaxial growth. Accordingly, mobility can be made higher than that in the case where first upper drift region 12a1 and second upper drift region 12b1 are formed by on implantation.

Moreover, according to the method for manufacturing MOSFET 1 according to the present embodiment, when viewed from connection region 17, silicon carbide substrate 10 further includes a first lower drift region 12a3 and a second lower drift region 12b3 located opposite to first upper drift region 12a1 and second upper drift region 12b1 and electrically connected to both first upper drift region 12a1 and second upper drift region 12b1. First upper drift region 12a1, second upper drift region 12b1, first lower drift region 12a3, and second lower drift region 12b3 are formed in the same epitaxial layer forming step. Accordingly, first upper drift region 12a1, second upper drift region 12b1, first lower drift region 12a3, and second lower drift region 12b3 can be formed by the simple method.

Moreover, according to the method for manufacturing MOSFET 1 according to the present embodiment, when viewed in the direction perpendicular to first main surface 10a, connection region 17 has a shape in conformity with an outer shape of polygon. Accordingly, an area of overlapping of gate insulating film 15 and connection region 17 becomes large, thereby effectively suppressing a high electric field from being applied to gate insulating film 15.

Moreover, according to the method for manufacturing MOSFET 1 according to the present embodiment, each of first upper drift region 12a1 and second upper drift region 12b1 has an impurity concentration of not more than 1×10¹⁶ cm⁻³. Accordingly, first upper drift region 12a1. and second upper drift region 12b1 can be depleted effectively. As a result, a high electric field can be suppressed effectively from being applied to gate insulating film 15 formed on first upper drift region 12a1 and second upper drift region 12b1.

Moreover, according to the method for manufacturing MOSFET 1 according to the present embodiment, the step of preparing the silicon carbide substrate includes steps of: forming a silicon carbide epitaxial layer 12 having first main surface 10a and having said first conductivity type; forming connection region 17 provided to be spaced away from main surface 10a by performing ion implantation into first main surface 10a; and forming first upper body region 13a1 and second upper body region 13b1 by performing ion implantation into first main surface 10a first upper body region 13a1 being electrically connected to connection region 17, second upper body region 13b1 being electrically connected to connection region 17. Accordingly, there can be provided a method for manufacturing MOSFET 1 so as to attain relaxed electric field concentration in gate insulating film 15 with a simple process.

Moreover, according to the modification of the method for manufacturing MOSFET 1 according to the present embodiment, the step of preparing the silicon carbide substrate includes steps of forming a silicon carbide epitaxial layer 12 having first main surface 10a and having n type; forming first upper body region 13a1 and second upper body region 13b1 by performing ion implantation into first main surface 10a, first upper body region 13a1 being exposed at first main surface 10a, second upper body region 13b1 being exposed at first main surface 10a; and forming connection region 17 by performing ion implantation into first main surface 10a, connection region 17 being electrically connected to both first upper body region 13a1 and second upper body region 13b1, connection region 17 being provided to be spaced away from first main surface 10a. Accordingly, there can be provided a method for manufacturing MOSFET 1 so as to attain relaxed electric field concentration in gate insulating film 15 with a simple process.

Moreover, according to the method for manufacturing MOSFET 1 according to the present embodiment, both first upper drift region 12a1 and second upper drift region 12b1 are formed by additionally performing ion implantation into first main surface 10a of silicon carbide epitaxial layer 12. Accordingly, the impurity concentration in each of first upper drift region 12a1 and second upper drift region 12b1 can be made high, thereby attaining improved breakdown voltage of MOSFET 1.

Although the present invention has been described and illustrated in detail, it is clearly understood that the same is by way of illustration and example only and is not to be taken by way of limitation, the scope of the present invention being interpreted by the terms of the appended claims.

What is claimed is:

1. A method for manufacturing a silicon carbide semiconductor device, comprising steps of:
preparing a silicon carbide substrate having a main surface; and
forming a gate insulating film on said main surface of said silicon carbide substrate,
when viewed in a direction perpendicular to said main surface, said silicon carbide substrate including a first cell region and a second cell region each having an. outer shape of polygon and sharing one side of said polygon,
said first cell region having a first source region, a first body region, and a first drift region, said first source region having first conductivity type, said first body region surrounding said first source region, said first body region having a second conductivity type different from said first conductivity type, said first body region having said outer shape of polygon when viewed in the direction perpendicular to said main surface, said first drift region having said first conductivity type, said first drift region being separated from said first source region by said first body region,
said second cell region having a second source region, a second body region, and a second drift region, said second source region having said first conductivity type, said second body region surrounding said second source region, said second body region having said second conductivity type, said second body region having said outer shape of polygon when viewed in the direction perpendicular to the main surface, said second drift region having said first conductivity type, said second drift region being separated from said second source region by said second body region, said second drift region being connected to said first drift region at said one side of said polygon,
when viewed in the direction perpendicular to said main surface, said silicon carbide substrate having a connection region provided to include an end portion of said one side, an apex of said first body region nearest to said end portion, and an apex of said second body region nearest to said end portion, said connection region being electrically connected to both said first body region and said second body region, said connection region having said second conductivity type.
when viewed in a direction parallel to said main surface, said first drift region and said second drift region being provided between said gate insulating film and said connection region,
in the step of forming said gate insulating film, said gate insulating film being formed on said main surface in contact with said first source region, said first body region, said first drift region, said second source region, said second body region, and said second drift region,
said connection region, said first body region, and said second body region being formed by ion implantation.

2. The method for manufacturing the silicon carbide semiconductor device according to claim 1, wherein both said first drift region and said second drift region are formed by epitaxial growth.

3. The method for manufacturing the silicon carbide semiconductor device according to claim 1, wherein
when viewed from said connection region, said silicon carbide substrate further includes a lower drift region located opposite to said first drift region and said second drift region and electrically connected to both said first drift region and said second drift region, and
said first drift region, said second drift region, and said lower drift region are formed in the same epitaxial layer firming step.

4. The method for manufacturing the silicon carbide semiconductor device according to claim 1, wherein when viewed in the direction perpendicular to said main surface, said connection region has a shape in conformity with an outer shape of polygon.

5. The method for manufacturing the silicon carbide semiconductor device according to claim 1, wherein each of said first drift region and said second drift region has an impurity concentration of not more than 1×10¹⁶ cm⁻³.

6. The method for manufacturing the silicon carbide semiconductor device according to claim 1, wherein
the step of preparing said silicon carbide substrate includes steps of:
forming a silicon carbide epitaxial layer having said main surface and having said first conductivity type;
forming said connection region provided to be spaced away from said main surface by performing ion implantation into said main surface; and
forming said first body region and said second body region by performing ion implantation into said main surface, said first body region being electrically connected to said connection region, said. second body region being electrically connected to said connection region.

7. The method for manufacturing the silicon carbide semiconductor device according to claim 1, wherein
the step of preparing said silicon carbide substrate includes steps of:
forming a silicon carbide epitaxial layer having said main surface and having said first conductivity type;
forming said first body region and said second body region by performing ion implantation into said main surface, said first body region being exposed at said main surface, said second body region being exposed at said main surface; and
forming said connection region by performing ion implantation into said main surface, said connection region being electrically connected to both said first body region and said second body region, said connection region being provided to be spaced away from said main surface.

8. The method for manufacturing the silicon carbide semiconductor device according to claim 6, wherein both said first drift region and said second drift region are formed by additionally performing ion implantation into said main surface of said silicon carbide epitaxial layer.
